(19) United States
(12) Patent Application Publication
(10) Pub. No.: US 2017/0345686 A1
(43) Pub. Date: Nov. 30, 2017

(54) SUBSTRATE TREATING APPARATUS AND SUBSTRATE TREATING METHOD

(71) Applicant: SEMES CO., LTD., Chungcheongnam-do (KR)

(72) Inventors: KIHOON CHOI, Chungcheongnam-do (KR); JINKYU KIM, Busan (KR); YOON JONG JU, Chungcheongnam-do (KR); MIN SUNG HAN, Chungcheongnam-do (KR); BYUNG MAN KANG, Chungcheongnam-do (KR)

(21) Appl. No.: 15/603,227

(22) Filed: May 23, 2017

(30) Foreign Application Priority Data
May 27, 2016 (KR) 10-2016-0065854

(51) Int. Cl. H01L 21/67; B08B 5/00; B08B 17/02; H01L 21/02

(52) U.S. Cl. CPC H01L 21/67051; H01L 21/02041; B08B 5/00; B08B 17/02; H01L 21/67173

(57) ABSTRACT

Disclosed are a liquid treating apparatus and a liquid treating method. The liquid treating apparatus includes a chamber that provides a space for processing a substrate, a support unit that is provided in the chamber to support the substrate, an ejection unit that has a nozzle for supplying a cleaning medium to the substrate supported by the support unit, and an auxiliary ejection unit that has an auxiliary nozzle for supplying a contamination prevention liquid to the substrate supported by the support unit.

### CROSS-REFERENCE TO RELATED APPLICATIONS

A claim for priority under 35 U.S.C. §119 is made to Korean Patent Application No. 10-2016-0065854 filed May 27, 2016, in the Korean Intellectual Property Office, the entire contents of which are hereby incorporated by reference.

### BACKGROUND

The inventive concept relates to a substrate treating apparatus and a substrate treating method.

Contaminants such as particles, organic contaminants, and metallic contaminants on a surface of a substrate greatly influence the characteristics and yield rate of a semiconductor device. Due to this, a cleaning process of removing various contaminants attached to a surface of a substrate is very important, and a process of cleaning a substrate is performed before and after unit processes for manufacturing a semiconductor.

### SUMMARY

The inventive concept provides a substrate treating apparatus that efficiently treats a substrate and a substrate treating method may be provided.

The inventive concept also provides a substrate treating apparatus that cleans a substrate in a drying method and a substrate treating method may be provided.

The inventive concept also provides a substrate treating apparatus that cleans a substrate at a normal pressure or a pressure that is adjacent to a normal pressure in a drying method and a substrate treating method may be provided.

The inventive concept also provides a substrate treating apparatus that cleans a substrate by using carbon dioxide and a substrate treating method may be provided.

The inventive concept also provides a substrate treating apparatus that has an improved cleaning efficiency and a substrate treating method may be provided.

The problems that are to be solved by the inventive concept are not limited to the above-mentioned problems, and the unmentioned problems will be clearly understood by those skilled in the art to which the inventive concept pertains from the specification and the accompanying drawings.

In accordance with an aspect of the inventive concept, there is provided a substrate treating apparatus including a chamber that provides a space for processing a substrate, a support unit that is provided in the chamber to support the substrate, an ejection unit that has a nozzle for supplying a cleaning medium to the substrate supported by the support unit, and an auxiliary ejection unit that has an auxiliary nozzle for supplying a contamination prevention liquid to the substrate supported by the support unit.

The auxiliary nozzle may supply the contamination prevention liquid to an area of the substrate, in which cleaning is performed by the cleaning medium.

The ejection unit may supply the cleaning medium to the substrate while the nozzle moves from an outer area of the substrate to a central area of the substrate.

The auxiliary ejection unit may supply the contamination prevention liquid to the substrate in a state in which a distance from the center of the substrate to the auxiliary nozzle is larger than a distance from the center of the substrate to the nozzle.

The cleaning medium may be carbon dioxide in an aerosol state.

An internal pressure of the chamber may be 0.75 bars to 1.25 bars.

The nozzle may include a contraction part which has an inlet, through which the cleaning medium is introduced, and a cross-sectional area of which decreases as it goes far from the inlet, an expansion part which has an ejection hole, through which the cleaning medium is ejected, and a cross-sectional area of which increases as it becomes closer to the ejection hole, and an orifice that is located between the contraction part and the expansion part.

The contamination prevention liquid may have a pH value that is larger than a pH value, by which particles are charged to have a negative potential according to a zeta potential.

The contamination prevention liquid may be an alkali liquid.

In accordance with another aspect of the inventive concept, there is provided a substrate treating method including initiating supply of a non-liquid cleaning medium to a rotating substrate, and supplying a contamination prevention liquid to an area of the substrate, in which the substrate is cleaned by the cleaning medium.

The supply of the cleaning medium may be performed, while the cleaning medium starts in an outer area of the substrate and moves to a central area of the substrate.

The supply of the contamination prevention liquid may be performed between an area of the substrate, in which the cleaning medium is supplied, and an outer area of the substrate.

The cleaning medium may be supplied in an aerosol state.

The treatment liquid may be carbon dioxide.

The supply of the cleaning medium is performed at a pressure of 0.75 bars to 1.25 bars.

The contamination prevention liquid may have a pH value that is larger than a pH value, by which particles are charged to have a negative potential according to a zeta potential.

The contamination prevention liquid may be an alkali liquid.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 is a plan view schematically illustrating a substrate treating system according to the inventive concept;

FIG. 2 is a schematic view illustrating an example of the substrate treating apparatus;

FIG. 3 is a view schematically illustrating an inner structure of a nozzle according to the inventive concept;

FIG. 4 illustrates pictures depicting a cleaning degree according to a ratio between areas of an orifice and an ejection hole;

FIG. 5 illustrates pictures depicting a cleaning degree of a substrate according to an internal pressure of a chamber;

FIG. 6 is a view illustrating a state in which an ejection unit initiates cleaning of a substrate;

FIG. 7 is a view illustrating a state in which the substrate is cleaned by the ejection unit and the contamination prevention liquid is supplied by the auxiliary ejection unit;

FIG. 8 is a view illustrating a locational relationship between the ejection unit 380 and the auxiliary ejection unit according to another embodiment; and

FIG. 9 is a view illustrating zeta potentials of several materials.

### DETAILED DESCRIPTION

Hereinafter, exemplary embodiments of the inventive concept will be described in more detail with reference to the accompanying drawings. The embodiments of the inventive concept may be modified in various forms, and the scope of the inventive concept should not be construed to be limited to the following embodiments. The embodiments of the inventive concept are provided to describe the inventive concept for those skilled in the art more completely. Accordingly, the shapes of the components of the drawings are exaggerated to emphasize clearer description thereof.

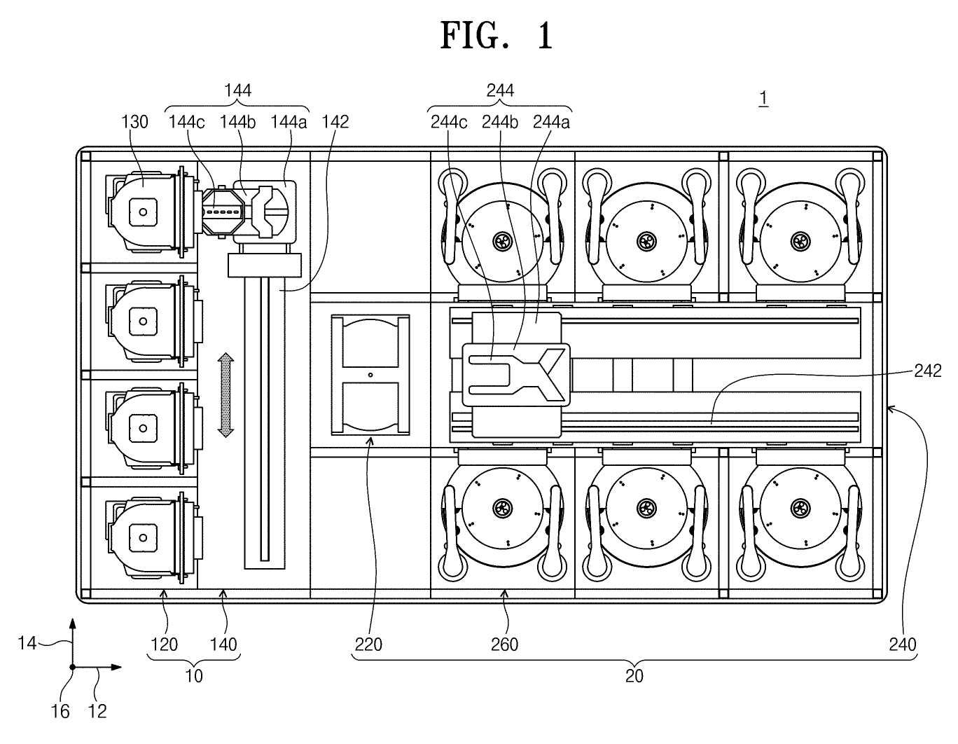

FIG. 1 is a plan view illustrating a substrate treating system according to an embodiment of the inventive concept.

Referring to FIG. 1, the substrate treating system 1 includes an index module 100 and a process executing module 200. The index module 100 includes a plurality of load ports 120 and a feeding frame 140. The load port 120, the feeding frame 140, and the process treating module 200 may be sequentially arranged in a row. Hereinafter, a direction in which the load port 120, the feeding frame 140, and the process treating module 200 will be referred to a first direction 12. A direction perpendicular to the first direction 12 when viewed from the top will be referred to as a second direction 14, and a direction normal to a plane including the first direction 12 and the second direction 14 will be referred to as a third direction 16.

A carrier 130, in which a substrate W is received, is seated on the load port 120. A plurality of load ports 120 are provided, and are arranged along the second direction 14 in a row. FIG. 1 illustrates that four load ports 120 are provided. However, the number of the load ports 120 may increase or decrease according to a condition, such as the process efficiency of the process treating module 200 or a footprint. A plurality of slots (not illustrated) provided to support peripheries of substrates W are formed in the carrier 130. A plurality of slots are provided in the third direction 16. The substrates W are stacked in the carrier 130 while being spaced apart from each other along the third direction 16. A front opening unified pod (FOUP) may be used as the carrier 130.

The process treating module 200 includes a buffer unit 220, a feeding chamber 240, and a plurality of process chambers 260. The feeding chamber 240 is arranged such that the lengthwise direction thereof is in parallel to the first direction 12. The process chambers 260 are arranged on opposite sides of the feeding chamber 240 along the second direction 14. The process chambers 260 situated on one side of the feeding chamber 240 and the process chambers 260 situated on an opposite side of the feeding chamber 240 are symmetrical to each other with respect to the feeding chamber 240. Some of the process chambers 260 are arranged along the lengthwise direction of the feeding chamber 240. Furthermore, some of the process chambers 260 are arranged to be stacked on each other. That is, the process chambers 260 having an array of A by B (A and B are natural numbers) may be arranged on one side of the feeding chamber 240. Here, A is the number of the process chambers 260 provided in a row along the first direction 12, and B is the number of the process chambers 260 provided in a row along the third direction 16. When four or six process chambers 260 are provided on one side of the feeding chamber 240, the process chambers 260 may be arranged in an array of 2 by 2 or 3 by 2. The number of the process chambers 260 may increase or decrease. Unlike the above-mentioned description, the process chambers 260 may be provided only on one side of the feeding chamber 240. Further, unlike the above-mentioned description, the process chambers 260 may be provided on one side or opposite sides of the feeding chamber 240 to form a single layer.

A buffer unit 220 is arranged between the feeding frame 140 and the feeding chamber 240. The buffer unit 220 provides a space in which the substrates W stay before being transported, between the feeding chamber 240 and the feeding frame 140. Slots (not illustrated) in which the substrates W are positioned are provided in the buffer unit 220, and a plurality of slots (not illustrated) are provided to be spaced apart from each other along the third direction 16. Faces of the buffer unit 220 that faces the feeding frame 140 and faces the feeding chamber 240 are opened.

The feeding frame 140 transports the substrates W between the carrier 130 seated on the load port 120 and the buffer unit 220. An index rail 142 and an index robot 144 are provided in the feeding frame 140. The index rail 142 is arranged such that the lengthwise direction thereof is in parallel to the second direction 14. The index robot 144 is installed on the index rail 142, and is linearly moved in the second direction 14 along the index rail 142. The index robot 144 has a base 144a, a body 144b, and a plurality of index arms 144c. The base 144a is installed to be moved along the index rail 142. The body 144b is coupled to the base 144a. The body 144b is provided to be moved along the third direction 16 on the base 144a. The body 144b is provided to be rotated on the base 144a. The index arms 144c are coupled to the body 144b, and are provided to be moved forwards and rearwards with respect to the body 144b. A plurality of index arms 144c are provided to be driven individually. The index arms 144c are arranged to be stacked so as to be spaced apart from each other along the third direction 16. Some of the index arms 144c are used when the substrates W are transported to the carrier 130 in the process module 200, and some of the index arms 155 may be used when the substrates W are transported from the carrier 130 to the process treating module 200. This structure may prevent particles generated from the substrates W before the process treatment from being attached to the substrates W after the process treatment in the process of carrying the substrates W in and out by the index robot 144.

The feeding chamber 240 transports the substrates W between the buffer unit 220 and the process chambers 260, and between the process chambers 260. A guide rail 242 and a main robot 244 are provided in the feeding chamber 240. The guide rail 242 is arranged such that the lengthwise direction thereof is in parallel to the first direction 12. The main robot 244 is installed on the guide rail 242, and is linearly moved along the first direction 12 on the index rail 242. The main robot 244 has a base 244a, a body 244b, and a plurality of main arms 244c. The base 244a is installed to be moved along the guide rail 242. The body 244b is coupled to the base 244a. The body 244b is provided to be moved along the third direction 16 on the base 244a. The body 244b is provided to be rotated on the base 244a. The main arms 244c are coupled to the body 244b, and are provided to be moved forwards and rearwards with respect to the body 244b. A plurality of main arms 244c are provided to be driven individually. The main arms 244c are arranged to be stacked so as to be spaced apart from each other along the third direction 16. The main arms 244c used when the substrates W are transported from the buffer unit 220 to the process chambers 260 and the main arms 244 used when the substrates W are transported from the process chambers 260 to the buffer unit 220 may be different.

Substrate treating apparatuses 300 that perform cleaning processes on the substrates W are provided in the process chambers 260. The substrate treating apparatuses 300 provided in the process chambers 260 may have different structures according to the types of performed cleaning processes. Selectively, the substrate treating apparatuses 300 in the process chambers 260 may have the same structure. Selectively, the process chambers 260 may be classified into a plurality of groups such that the substrate treating apparatuses 300 provided in the process chambers 260 pertaining to the same group have the same structure and the substrate treating apparatuses 300 provided in the process chambers 260 pertaining to different groups has different structures. For example, when the process chambers 260 are classified into two groups, the first group of process chambers 260 may be provided on one side of the feeding chamber 240 and the second group of process chambers 260 may be provided on an opposite side of the feeding chamber 240. Selectively, the first group of process chambers 260 may be provided on the lower side of the feeding chamber 240 and the second group of process chambers 260 may be provided on the upper side of the feeding chamber 240, on opposite sides of the feeding chamber 240. The first group of process chambers 260 and the second group of process chambers 260 may be classified according to the kinds of the used chemicals or the types of cleaning methods.

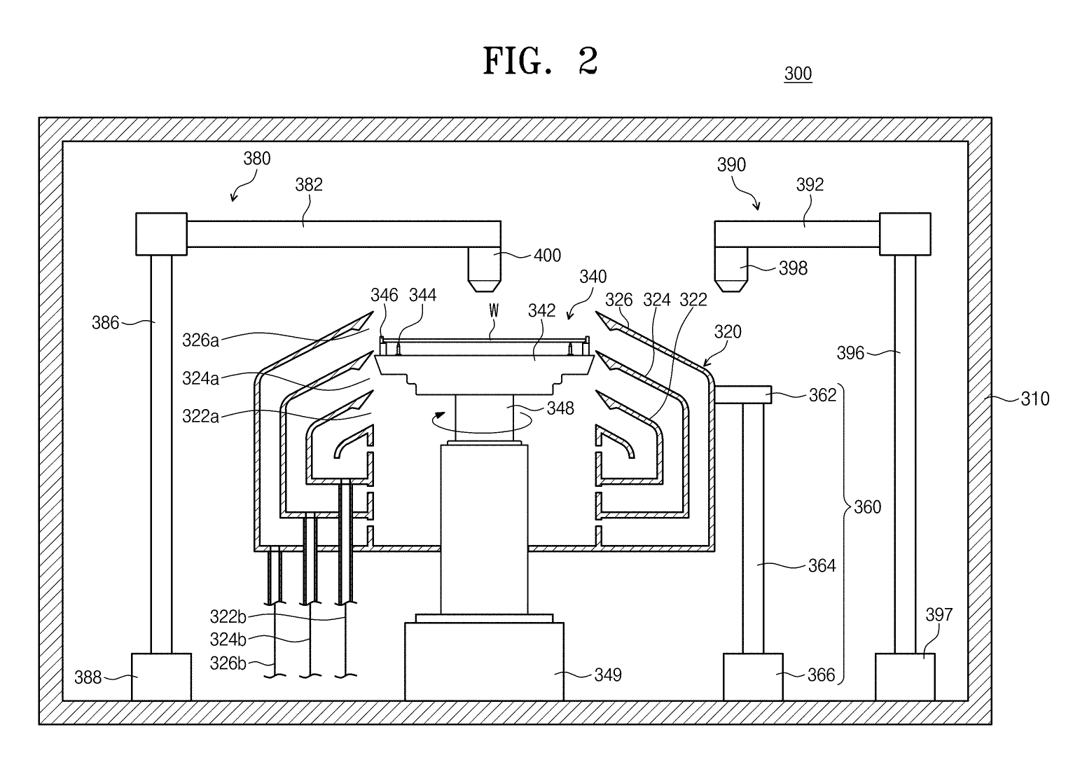

FIG. 2 is a view illustrating a substrate treating apparatus according to an embodiment of the inventive concept;

Referring to FIG. 2, the substrate treating apparatus 300 includes a chamber 310, a cup 320, a support unit 340, an elevation unit 360, an ejection unit 380, and an auxiliary ejection unit 390.

The chamber 310 provides a space in the interior thereof. The internal pressure of the chamber 310 may be maintained at 0.01 bars to 1 bars. Further, the internal pressure of the chamber 310 may be maintained at 0.75 bars to 1.25 bars. For example, the internal pressure of the chamber 310 may be a normal pressure.

The cup 320 is located in a space in the chamber 310. The cup 320 has a space for performing a substrate treating process, and an upper side of the housing 320 is opened. The cup 320 has an inner recovery vessel 322, an intermediate recovery vessel 324, and an outer recovery vessel 326. The recovery vessels 322, 324, and 326 recover different treatment fluids used in the process. The inner recovery vessel 322 has an annular ring shape that surrounds the support unit 340, the intermediate recovery vessel 324 has an annular ring shape that surrounds the inner recovery vessel 322, and the outer recovery vessel has an annular ring shape that surrounds the intermediate recovery vessel 324. An inner space 322a of the inner recovery vessel 322, a space 324a between the inner recovery vessel 322 and the intermediate recovery vessel 324, and a space 326a between the intermediate recovery vessel 324 and the outer recovery vessel 326 function as inlets 410 through which the treatment fluids are introduced into the inner recovery vessel 322, the intermediate recovery vessel 324, and the outer recovery vessel 326. Recovery lines 322b, 324b, and 326b extending from the recovery vessels 322, 324, and 326 perpendicularly in the downward direction of the bottom surfaces thereof are connected to the recovery vessels 322, 324, and 326, respectively. The recovery lines 322b, 324b, and 326b discharge the treatment fluids introduced through the recovery vessels 322, 324, 326, respectively. The discharged treatment fluids may be reused through an external treatment fluid recycling system (not illustrated).

The support unit 340 is arranged in a treatment space of the cup 320. The support unit 340 supports and rotates the substrate during the process. The support unit 340 has a spin head 342, a plurality of support pins 344, a plurality of chuck pins 346, a drive shaft 348, and a driving unit 349. The spin head 342 has an upper surface having a substantially circular shape when viewed from the top. The drive shaft 348 that may be rotated by a driver 349 is fixedly coupled to the bottom of the spin head 342. If the driving shaft 348 is rotated, the spin head 342 is rotated. The spin head 342 includes a support pin 344 and a chuck pin 346 to support the substrate. A plurality of support pins 344 are provided. The support pins 344 may be arranged to be spaced apart from each other at a periphery of the upper surface of the spin head 342 and protrude upwards from the spin head 342. The support pins 344 are arranged to have a generally annular ring shape through combination thereof. The support pins 344 support a periphery of a bottom surface of the substrate such that the substrate W is spaced apart from the upper surface of the spin head 342 by a predetermined distance. A plurality of chuck pins 346 are provided. The chuck pins 346 are arranged to be more distant from the center of the spin head 342 than the support pins 344. The chuck pins 346 are provided to protrude upwards from the spin head 342. The chuck pins 346 support a side surface of the substrate such that the substrate is not separated laterally from a proper place when the support unit 340 is rotated. The chuck pins 346 are provided to be linearly moved between a standby position and a support position along a radial direction of the spin head 342. The standby position is a position that is more distant from the center of the spin head 342 than the support position. When the substrate is loaded on or unloaded from the support unit 340, the chuck pins 346 are located at the standby position, and when a process is performed on the substrate, the chuck pins 346 are located at the support position. The chuck pins 346 are in contact with the side of the substrate at the support position.

The elevation unit 360 linearly moves the cup 320 upwards and downwards. The elevation unit 360 may move the plurality of recovery vessels 322, 324, and 326 of the cup 320. Although not illustrated, the recovery vessels may be individually moved. When the cup 320 is moved upwards and downwards, a relative height of the cup 320 to the support unit 340 is changed. The elevation unit 360 has a bracket 362, a movable shaft 364, and a driver 366. The bracket 362 is fixedly installed on an outer wall of the cup 320, and the movable shaft 364 that is moved upwards and downwards by the driver 366 is fixedly coupled to the bracket 362. The cup 320 is lowered such that, when the substrate W is positioned on the support unit 340 or is lifted from the support unit 340, the support unit 340 protrudes to the upper side of the cup 320. When the process is performed, the height of the cup 320 is adjusted such that the treatment fluid is introduced into the preset recovery vessel 360 according to the kind of the treatment fluid supplied to the substrate W. For example, the substrate is located at a height corresponding to an interior space 322a of the inner recovery vessel 322 while the substrate is treated by a first treatment fluid. Further, the substrate may be located at a height corresponding to a space 324a between the inner recovery vessel 322 and the intermediate recovery vessel 324 and a space 326a between the intermediate recovery vessel 324 and the outer recovery vessel 326 while the substrate is treated by a second treatment fluid and a third treatment fluid. Unlike those described above, the elevation unit 360 may move the support unit 340, instead of the cup 320, upwards and downwards. Further, unlike the above description, the cup 320 may have a single recovery vessel 322.

The ejection unit 380 ejects a cleaning medium onto the substrate W. The cleaning medium is supplied to the substrate W in a non-liquid material state. As an example, the cleaning medium may be supplied to the substrate in an aerosol state. As an example, the material supplied in an aerosol state may be carbon dioxide. The ejection unit 380 may be rotated. One or a plurality of ejection units 380 may be provided. The ejection unit 380 has a nozzle support 382, a support 386, a driver 388, and a nozzle 400. The lengthwise direction of the support 386 is provided along the third direction 16, and the driver 388 is coupled to a lower end of the support 386. The driver 388 rotates and elevates the support 386. The nozzle support 382 is coupled to an end of the support 386, which is opposite to an end of the support 386 coupled to the driver 388, perpendicularly to the support 386. The nozzle 400 is installed on a bottom surface of an end of the nozzle support 382. The nozzle 400 is moved to a process location and a standby location by the driver 388. The process location is a location at which the nozzle 400 is arranged at an vertical upper portion of the cup 320, and the standby location is a location that deviates from the vertical upper portion of the cup 320.

The ejection unit 390 ejects the treatment fluid onto the substrate W. The auxiliary ejection unit 390 may be rotated. The auxiliary ejection unit 390 has an auxiliary nozzle 398, a support 392, an auxiliary support 396, an auxiliary driver 397, and an auxiliary nozzle 398. The lengthwise direction of the auxiliary support 396 is provided along the third direction 16, and the auxiliary driver 396 is coupled to a lower end of the auxiliary support 397. The auxiliary driver 397 moves the auxiliary support 396. As an example, the auxiliary driver 397 may rotate the auxiliary support 396. Further, the auxiliary driver 397 may elevate the auxiliary support 396. The auxiliary nozzle support 382 is coupled to an upper side of the auxiliary support 396. The auxiliary nozzle 398 is installed on the bottom surface of an end of the auxiliary nozzle support 382. The auxiliary nozzle 397 moves to a process location and a standby location by the auxiliary driver 388. The process location is a location at which the auxiliary nozzle 398 is arranged at an vertical upper portion of the cup 320, and the standby location is a location of the auxiliary nozzle 398, which deviates from the vertical upper portion of the cup 320.

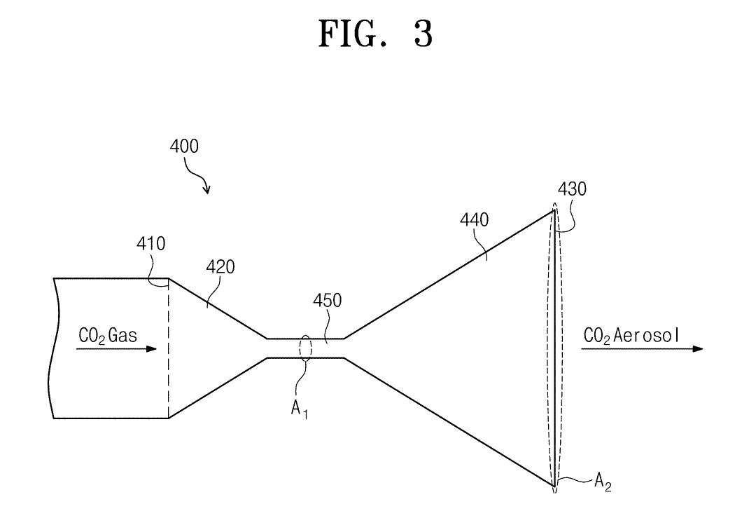

FIG. 3 is a view schematically illustrating an inner structure of a nozzle according to an embodiment.

The nozzle 400 has a contraction part 420, an expansion part 440, and an orifice 450. The contraction part 420, the orifice 450, and the expansion part 440 are sequentially provided. The contraction part 420 has an inlet 410. A cleaning medium is introduced through the inlet 410. The cross-section of the contraction part 420 decreases as it goes far away from the inlet 410. For example, the contraction part 420 may have a conical shape.

The cleaning medium introduced through the inlet 410 may be a single gas. The cleaning medium may be carbon dioxide. The supply pressure of the introduced cleaning medium may be 20 bars to 60 bars. The supply pressure of the cleaning medium may be 45 bars to 55 bars.

The expansion part 440 has an ejection hole 430. The ejection hole 430 ejects a cleaning medium. The cross-section of the expansion part 440 increases as it becomes closer to the ejection hole 430. For example, the expansion part 440 may have a conical shape. When being ejected from the ejection hole 430, the cleaning medium is ejected as solid particles.

The orifice 450 is located between the contraction part 420 and the expansion part 440. The orifice 450 may have a constant cross-sectional area along a lengthwise direction thereof.

The area of the ejection hole 430 may be 4 to 14 times as large as the cross-section of the orifice 450. The area of the ejection hole 430 may be 6 to 10 times as larger as the cross-section of the orifice 450.

That is, the area of the ejection hole 430 may be 4 to 14 times as large as the sectional area of the passage of the orifice 450, which is cut perpendicularly to a lengthwise direction of the orifice 450. Further, the area of the ejection hole 430 may be 6 to 10 times as large as the sectional area of the passage of the orifice 450.

According to an example, the diameter of the orifice 450 may be 0.24 mm to 0.6 mm, and the diameter of the ejection hole 430 may be 0.9 mm to 3.0 mm. Further, the diameter of the orifice may be 0.3 mm to 0.5 mm, and the diameter of the ejection hole may be 0.9 mm to 1.1 mm.

According to an example, the area of the orifice 450 may be 0.05 mm² to 0.28 mm², and the area of the ejection hole 430 may be 0.7 mm² to 7 mm². Further, the area of the orifice may be 0.10 mm² to 0.14 mm², and the area of the ejection hole may be 0.7 mm² to 1.4 mm².

Under the above-mentioned condition, the cleaning medium ejected from the ejection hole 430 may be ejected at a high speed and a high pressure such that the substrate may be sufficiently cleaned even without using a carrier gas. A cleaning efficiency of the substrate will be described with reference to an experimental result, which will be described below in relation to the above description.

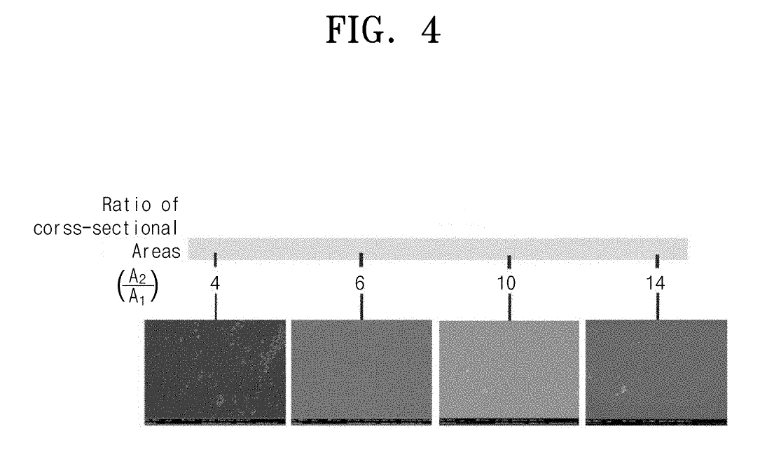

FIG. 4 illustrates pictures depicting a cleaning degree of the substrate according to a ratio of the areas of the orifice 450 and the ejection hole 430.

Hereinafter, the relatively bright dots in the pictures are impurities residing after the cleaning. It means that as a larger amount of bright dots is distributed, the cleaning is more incomplete.

The following experiments were performed in a state in which the internal pressure of the chamber is not a vacuum pressure. Further, as a cleaning medium, only carbon dioxide in a single gaseous state was supplied without using a separate carrier gas.

It can be seen from FIG. 4 that the substrate may be cleaned only with a single carbon dioxide gas when the ratio of the cross-sectional area A1 of the orifice 450 and the area A2 of the ejection hole 430 is 4 to 14. In particular, when the ratio of the cross-sectional area A1 of the orifice 450 and the cross-sectional area of the ejection hole 430 is 6 to 10, the impurities of the substrate are effectively cleaned.

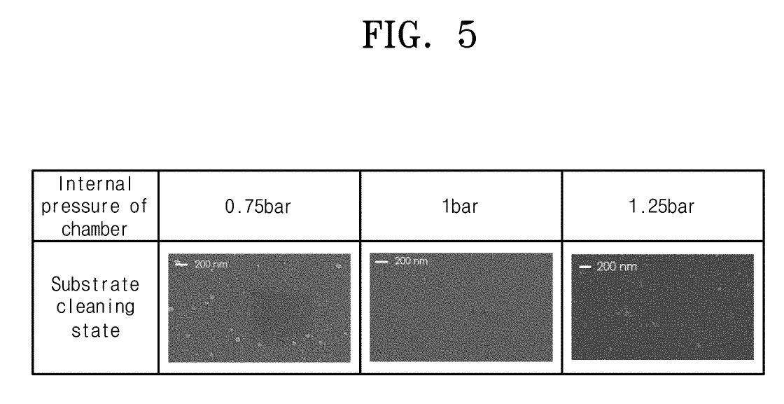

FIG. 5 illustrates pictures depicting a cleaning degree of a substrate according to an internal pressure of a chamber.

As described above, the nozzle 400, of which ratio of the cross-sectional area A1 of the orifice 450 and the area A2 of the ejection hole 430 is 6 to 10, was used, and the experiment was performed in a state in which the internal pressure of the chamber was not a vacuumed pressure. As an example, the experiments were performed when the internal pressures of the chamber is 0.75 bars, 1 bars, and 1.25 bars, respectively. The pressure at which the cleaning medium is supplied to the inlet 410 of the nozzle 400 was maintained at 45 bars to 55 bars. Referring to FIG. 5, it can be seen that the substrate was cleaned even when the internal pressure of the chamber is not a vacuumed pressure. In particular, the substrate was effectively cleaned at between 0.75 bars and 1.25 bars. Accordingly, the cleaning is performed by the cleaning medium while the chamber 310 is provided at a normal pressure or a pressure (between 0.75 bars and 1.25 bar) that is adjacent to a normal pressure, and thus a liquid state contamination prevention liquid, which will be described below, may be ejected to the substrate.

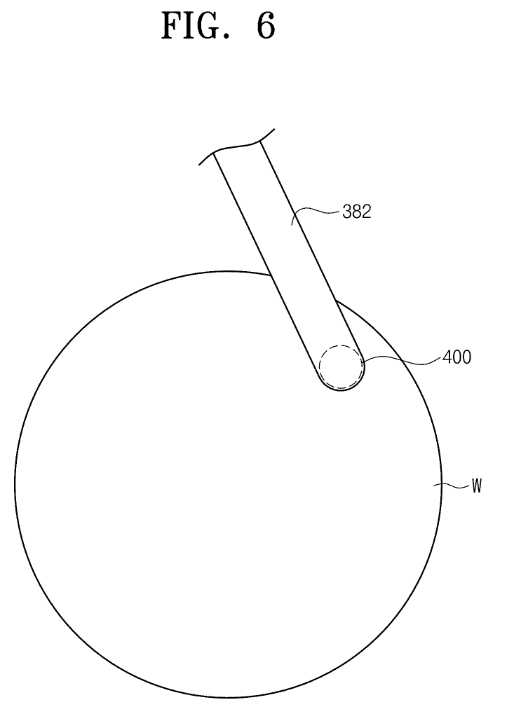

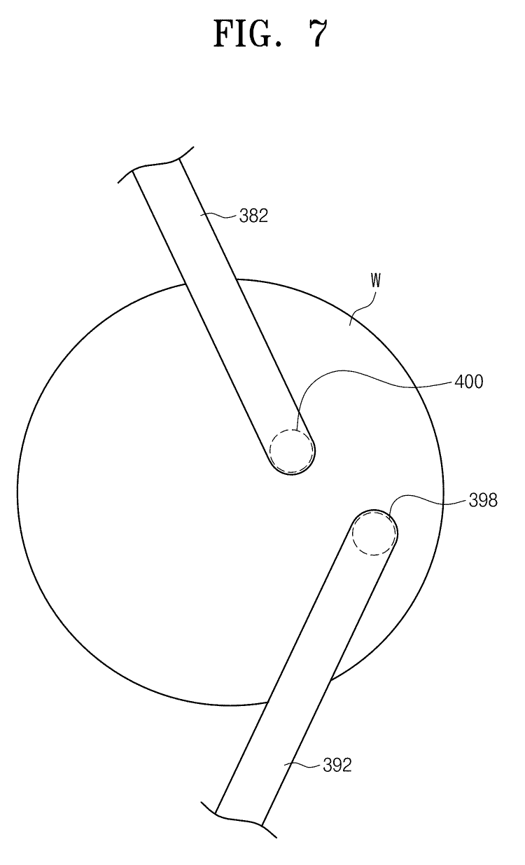

FIG. 6 is a view illustrating a state in which the ejection unit 380 has initiated the cleaning of the substrate W. FIG. 7 is a view illustrating a state in which the substrate is cleaned by the ejection unit and the contamination prevention liquid is supplied by the auxiliary ejection unit 390.

Referring to FIGS. 6 and 7, first, the substrate W is cleaned by the ejection unit 380. The cleaning of the substrate W by the ejection unit 380 is initiated in an outer area of the substrate W. Thereafter, the ejection unit 380 supplies the cleaning medium while the nozzle 400 is driven to be moved towards the center of the substrate W. While the nozzle 400 supplies the cleaning medium, the substrate W may be rotated.

In an area in which the substrate W is cleaned by the ejection unit 380, the contamination prevention liquid is supplied by the auxiliary ejection unit 390. The ejection unit 390 initiates supply of the contamination prevention liquid in an outer area of the substrate W. Thereafter, the auxiliary ejection unit 390 supplies the contamination prevention liquid while the auxiliary nozzle 398 is driven to be moved towards the center of the substrate W. The contamination prevention liquid prevents particles spattering to an upper side of the substrate due to the cleaning medium from being attached to a surface of the substrate W again. The auxiliary nozzle 398 supplies the contamination prevention liquid to the substrate W in a state in which the auxiliary nozzle 398 is located on an outside of the substrate W. Accordingly, even when the contamination prevention liquid spatters to the outside of the substrate W due to rotation of the substrate W, it does not influence an area in which the cleaning is not performed by the ejection unit 380.

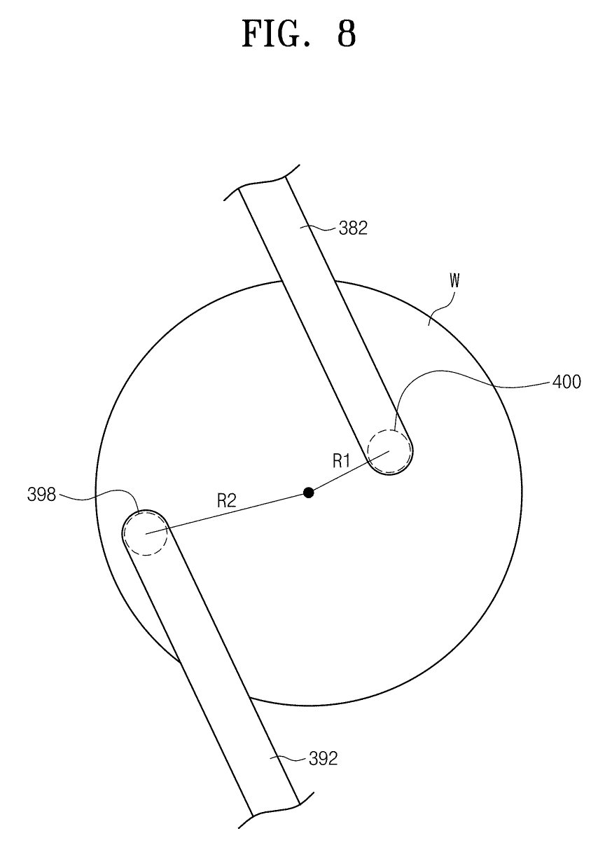

FIG. 8 is a view illustrating a locational relationship between the ejection unit 380 and the auxiliary ejection unit 390 according to another embodiment.

Referring to FIG. 8, the auxiliary ejection unit 390 may be located in an area that is opposite to the ejection unit 380 with respect to the center of the substrate W. Then, a distance R1 from the center of the substrate W to the nozzle 400 is shorter than a distance R2 from the center of the substrate W to the auxiliary nozzle 398. Accordingly, similar to FIG. 7, even when the contamination prevention liquid spatters to the outside of the substrate W due to rotation of the substrate W, it does not influence an area in which the cleaning is not performed by the ejection unit 380.

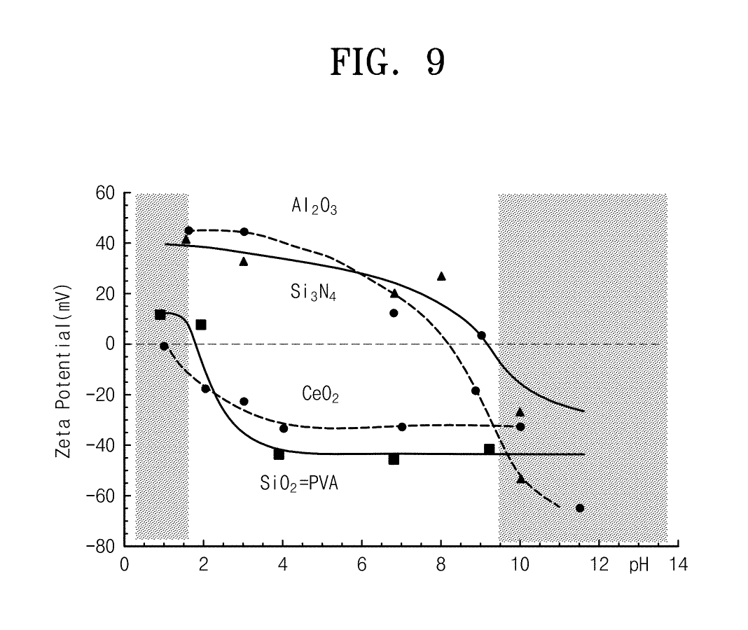

FIG. 9 is a view illustrating zeta potentials of several materials.

Referring to FIG. 9, it can be seen that a potential of a surface of a material varies according to a pH of a liquid if the material meets a liquid. Accordingly, when the particles spattering from the substrate W drop in an area in which the contamination prevention liquid is applied, they have a potential according to the zeta potential. Accordingly, the contamination prevention liquid supplied by the auxiliary ejection unit 390 may be a liquid having a pH that considers a zeta potential of particles. In detail, the pH value of the contamination prevention liquid may be a pH value by which particles are charged to have a negative potential according to zeta potential. As an example, the contamination prevention liquid may be an alkali liquid. Accordingly, when the particles spattering from the substrate W drop in an area in which the contamination prevention liquid is applied, they have a negative potential. Further, a surface of the substrate W has a negative potential due to the cleaning of the substrate W by the cleaning medium or the contamination prevention liquid. Accordingly, an attractive force is generated between a surface of the substrate W and the particles so that particles may be certainly prevented from being adsorbed to the surface of the substrate W.

According to an embodiment of the inventive concept, a substrate treating apparatus that efficiently treats a substrate and a substrate treating method may be provided.

Further, according to an embodiment of the inventive concept, a substrate treating apparatus that cleans a substrate in a drying method and a substrate treating method may be provided.

Further, according to an embodiment of the inventive concept, a substrate treating apparatus that cleans a substrate at a normal pressure or a pressure that is adjacent to a normal pressure in a drying method and a substrate treating method may be provided.

Further, according to an embodiment of the inventive concept, a substrate treating apparatus that cleans a substrate by using carbon dioxide and a substrate treating method may be provided.

According to an embodiment of the inventive concept, a substrate treating apparatus that has an improved cleaning efficiency and a substrate treating method may be provided.

The above description exemplifies the inventive concept. Furthermore, the above-mentioned contents describe the exemplary embodiment of the inventive concept, and the inventive concept may be used in various other combinations, changes, and environments. That is, the inventive concept can be modified and corrected without departing from the scope of the inventive concept that is disclosed in the specification, the equivalent scope to the written disclosures, and/or the technical or knowledge range of those skilled in the art. The written embodiment describes the best state for implementing the technical spirit of the inventive concept, and various changes required in the detailed application fields and purposes of the inventive concept can be made. Accordingly, the detailed description of the inventive concept is not intended to restrict the inventive concept in the disclosed embodiment state. Furthermore, it should be construed that the attached claims include other embodiments.

What is claimed is:

1. A substrate treating apparatus comprising:
a chamber that provides a space for processing a substrate;
a support unit that is provided in the chamber to support the substrate;
an ejection unit that has a nozzle for supplying a cleaning medium to the substrate supported by the support unit; and
an auxiliary ejection unit that has an auxiliary nozzle for supplying a contamination prevention liquid to the substrate supported by the support unit.

2. The substrate treating apparatus of claim 1, wherein the auxiliary nozzle supplies the contamination prevention liquid to an area of the substrate, in which cleaning is performed by the cleaning medium.

3. The substrate treating apparatus of claim 1, wherein the ejection unit supplies the cleaning medium to the substrate while the nozzle moves from an outer area of the substrate to a central area of the substrate.

4. The substrate treating apparatus of claim 3, wherein the auxiliary ejection unit supplies the contamination prevention liquid to the substrate in a state in which a distance from the center of the substrate to the auxiliary nozzle is larger than a distance from the center of the substrate to the nozzle.

5. The substrate treating apparatus of claim 1, wherein the cleaning medium is carbon dioxide in an aerosol state.

6. The substrate treating apparatus of claim 1, wherein an internal pressure of the chamber is 0.75 bars to 1.25 bars.

7. The substrate treating apparatus of claim 1, wherein the nozzle comprises:
a contraction part which has an inlet, through which the cleaning medium is introduced, and a cross-sectional area of which decreases as it goes far from the inlet;
an expansion part which has an ejection hole, through which the cleaning medium is ejected, and a cross-sectional area of which increases as it becomes closer to the ejection hole; and
an orifice that is located between the contraction part and the expansion part.

8. The substrate treating apparatus of claim 1, wherein the contamination prevention liquid has a pH value that is larger than a pH value, by which particles are charged to have a negative potential according to a zeta potential.

9. The substrate treating apparatus of claim 1, wherein the contamination prevention liquid is an alkali liquid.

10. A substrate treating method comprising:
initiating supply of a non-liquid cleaning medium to a rotating substrate; and
supplying a contamination prevention liquid to an area of the substrate, in which the substrate is cleaned by the cleaning medium.

11. The substrate treating method of claim 10, wherein the supply of the cleaning medium is performed, while the cleaning medium starts in an outer area of the substrate and moves to a central area of the substrate.

12. The substrate treating method of claim 11, wherein the supply of the contamination prevention liquid is performed between an area of the substrate, in which the cleaning medium is supplied, and an outer area of the substrate.

13. The substrate treating method of claim 10, wherein the cleaning medium is supplied in an aerosol state.

14. The substrate treating method of claim 13, wherein the treatment liquid is carbon dioxide.

15. The substrate treating method of claim 13, wherein the supply of the cleaning medium is performed at a pressure of 0.75 bars to 1.25 bars.

16. The substrate treating method of claim 10, wherein the contamination prevention liquid has a pH value that is larger than a pH value, by which particles are charged to have a negative potential according to a zeta potential.

17. The substrate treating method of claim 10, wherein the contamination prevention liquid is an alkali liquid.
